(19) United States
(12) Patent Application Publication
(10) Pub. No.: US 2014/0151630 A1
(43) Pub. Date: Jun. 5, 2014

(54) PROTECTION FOR THE EPITAXIAL STRUCTURE OF METAL DEVICES

(71) Applicants: Feng-Hsu Fan, Jhonghe City (TW); Trung Tri Doan, Baoshan Township (TW); Chuong Anh Tran, Baoshan Township (TW); Chen-Fu Chu, Hsinchu City (TW); Chao-Chen Cheng, Hsinchu City (TW); Jiunn-Yi Chu, Chubei City (TW); Wen-Huang Liu, Guan-Xi Town (TW); Hao-Chun Cheng, Donggang Township (TW); Jui-Kang Yen, Taipei City (TW)

(72) Inventors: Feng-Hsu Fan, Jhonghe City (TW); Trung Tri Doan, Baoshan Township (TW); Chuong Anh Tran, Baoshan Township (TW); Chen-Fu Chu, Hsinchu City (TW); Chao-Chen Cheng, Hsinchu City (TW); Jiunn-Yi Chu, Chubei City (TW); Wen-Huang Liu, Guan-Xi Town (TW); Hao-Chun Cheng, Donggang Township (TW); Jui-Kang Yen, Taipei City (TW)

(21) Appl. No.: 13/693,199

(22) Filed: Dec. 4, 2012

(51) Int. Cl. H01L 33/04

(52) U.S. Cl. CPC H01L 33/04
USPC 257/9

(57) ABSTRACT

Techniques for fabricating metal devices, such as vertical light-emitting diode (VLED) devices, power devices, laser diodes, and vertical cavity surface emitting laser devices, are provided. Devices produced accordingly may benefit from greater yields and enhanced performance over conventional metal devices, such as higher brightness of the light-emitting diode and increased thermal conductivity. Moreover, the invention discloses techniques in the fabrication arts that are applicable to GaN-based electronic devices in cases where there is a high heat dissipation rate of the metal devices that have an original non-(or low) thermally conductive and/or non-(or low) electrically conductive carrier substrate that has been removed.

### CROSS-REFERENCE TO RELATED APPLICATIONS

This application is a continuation of U.S. patent application Ser. No. 13/310,552, filed Dec. 2, 2011, which is a divisional of U.S. patent application Ser. No. 11/548,642, filed Oct. 11, 2006, which are incorporated herein by reference.

### TECHNICAL FIELD

Embodiments of the present invention generally relate to a metal device, such as a light emitting diode (LED), a power device, a laser diode, and a vertical cavity surface emitting device, and methods for fabricating the same.

### BACKGROUND

Microelectronic devices, such as metal devices, are playing an increasingly important role in our daily life. For instance, LEDs have become ubiquitous in many applications, such as mobile phones, appliances, and other electronic devices. Recently, the demand for nitride-based semiconductor materials (e.g., having gallium nitride or GaN) for opto-electronics has increased dramatically for applications ranging from video displays and optical storage to lighting and medical instruments.

Conventional blue LEDs are formed using compound semiconductor materials with nitride, such as GaN, AlGaN, InGaN, and AlInGaN. Most of the semiconductor layers of these light-emitting devices are epitaxially formed on electrically non-conductive sapphire substrates.

### SUMMARY OF THE INVENTION

One embodiment of the invention provides a semiconductor die. The semiconductor die generally includes a metal substrate, an epitaxial structure disposed above the metal substrate, and an electrically non-conductive material substantially covering the lateral surfaces of the epitaxial structure. The epitaxial structure generally includes a p-doped layer coupled to the metal substrate and an n-doped layer disposed above the p-doped layer.

Another embodiment of the invention provides a vertical light-emitting diode (VLED) die. The VLED die generally includes a metal substrate, an epitaxial structure disposed above the metal substrate, and an electrically non-conductive material surrounding the epitaxial structure except for the upper surface of the n-GaN layer and a portion of the p-GaN layer coupled to the metal substrate. The epitaxial structure generally includes a p-GaN layer coupled to the metal substrate, a multiple well quantum (MQW) layer for emitting light coupled to the p-doped layer, and an n-GaN layer coupled to the MQW layer.

Yet another embodiment of the invention provides a semiconductor die. The semiconductor die generally includes a metal substrate, a p-doped layer coupled to the metal substrate, a multiple quantum well (MQW) layer disposed above the p-doped layer, an n-doped layer disposed above the MQW layer, and an electrically non-conductive material substantially covering at least the lateral surfaces of the MQW layer.

Yet another embodiment of the invention provides a wafer assembly. The wafer assembly generally includes a substrate, a plurality of epitaxial structures disposed on the substrate, and an electrically non-conductive material substantially covering the lateral surfaces of each of the plurality of epitaxial structures. Each of the epitaxial structures generally includes an n-doped layer coupled to the substrate and a p-doped layer disposed above the n-doped layer.

Yet another embodiment of the invention is a method. The method generally includes providing a wafer assembly comprising a plurality of semiconductor dies formed on a carrier substrate, the dies separated by street areas formed between the dies and having an n-doped layer coupled to the carrier substrate and a p-doped layer disposed above the n-doped layer; filling in at least a portion of the street areas with an electrically non-conductive material; and forming a metal plate above the plurality of semiconductor dies such that the non-conductive material sustains the metal plate, at least during formation, at or above the maximum height of the p-doped layer for the plurality of semiconductor dies.

Yet another embodiment of the invention is a method. The method generally includes providing a wafer assembly comprising a plurality of VLED dies formed on a carrier substrate, the VLED dies separated by street areas formed between the dies and having an n-doped layer coupled to the carrier substrate, a multiple quantum well (MQW) layer for emitting light disposed above the n-doped layer, and a p-doped layer disposed above the MQW layer; filling in at least a portion of the street areas with an electrically non-conductive material; and forming a metal plate above the plurality of VLED dies such that the non-conductive material sustains the metal plate, at least during formation, at or above the maximum height of the p-doped layer for the plurality of VLED dies.

### BRIEF DESCRIPTION OF THE DRAWINGS

FIG. 1 is a cross-sectional schematic representation of a wafer illustrating the layers of an epitaxial structure deposited on a carrier substrate in accordance with an embodiment of the invention.

FIG. 2 illustrates defined devices with street areas between devices in accordance with an embodiment of the invention.

FIG. 3 illustrates adding a mirror to the epitaxial structure of FIG. 2 in accordance with embodiments of the invention.

FIGS. 4a-d illustrate adding electrically non-conductive material to the wafer of FIG. 3b in accordance with embodiments of the invention.

FIGS. 5a-c illustrate options for the non-conductive material and an insulative layer in accordance with embodiments of the invention.

FIGS. 6a-c illustrate options for the mirror, the insulative layer, and the non-conductive material in accordance with embodiments of the invention.

FIG. 7 illustrates depositing a seed metal, one or more additional metal layers, and a conductive protection layer in accordance with an embodiment of the invention.

FIGS. 8a-b illustrate removal of the carrier substrate from the wafer assembly in accordance with embodiments of the invention.

FIG. 9 illustrates filling in portions of a mesa with metal in accordance with an embodiment of the invention.

FIG. 10 is a flowchart of a method for fabricating vertical light-emitting diode (VLED) devices in accordance with an embodiment of the invention.

### DETAILED DESCRIPTION

Embodiments of the invention provide improvements in the art of light-emitting diodes (LEDs) and methods of fabrication, including higher yield and better performance such as higher brightness of the LED and better thermal conductivity. Moreover, the invention discloses improvements in the fabrication arts that are applicable to GaN-based electronic devices such as vertical light-emitting diode (VLED) devices, power devices, laser diodes, and vertical cavity surface emitting laser devices in cases where there is a high heat dissipation rate of the metal devices that have an original non-(or low) thermally conductivity and/or non-(or low) electrically conductive substrate that has been removed.

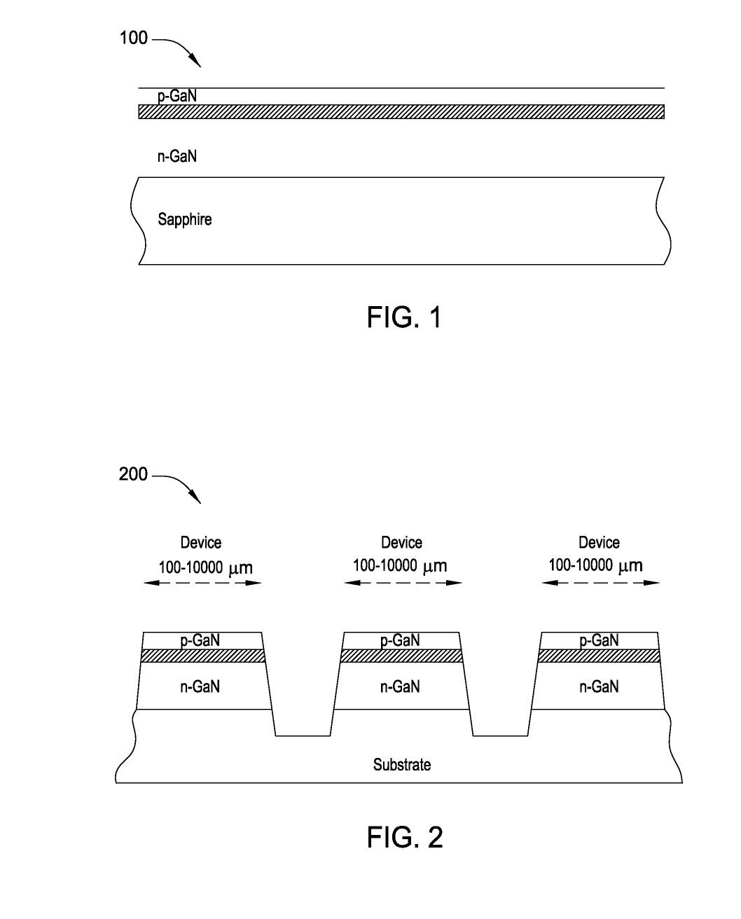

Referring to FIG. 1, a wafer 100 may comprise a carrier substrate. Although the carrier substrate may be composed of sapphire, silicon carbide (SiC), silicon, germanium, zinc oxide (ZnO), or gallium arsenide (GaAs), the examples provided herein will be directed to a carrier substrate that is composed of sapphire. A multilayer epitaxial structure (EPI) may be formed to have an n-type GaN layer, one or more quantum wells with InGaN/GaN layers, and a p-type AIGaN/GaN layer. Although the n-type layer and the p-type layer may comprise various compound semiconductor materials, such as GaN, AIGaN, InGaN, and AIInGaN, n-GaN and p-GaN layers will be described henceforth.

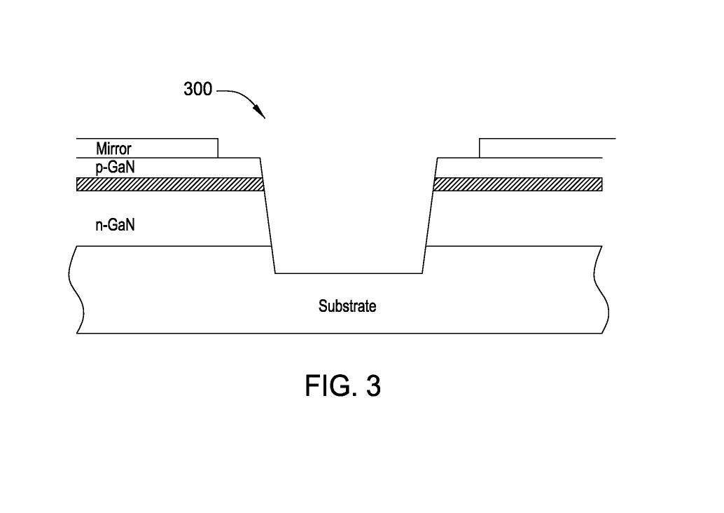

Referring now to FIG. 2, various methods may be used to define one or more devices using a process that cuts directly through a p-n junction and potentially into the carrier substrate, as is shown at 200. These methods are known to those skilled in the art and will not be described herein.

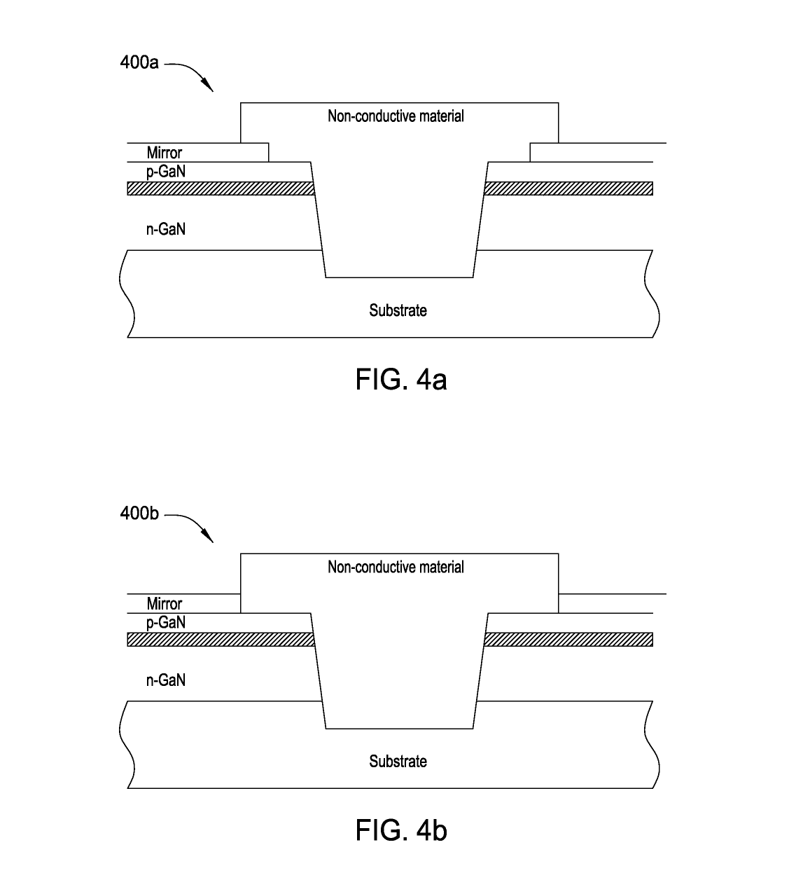

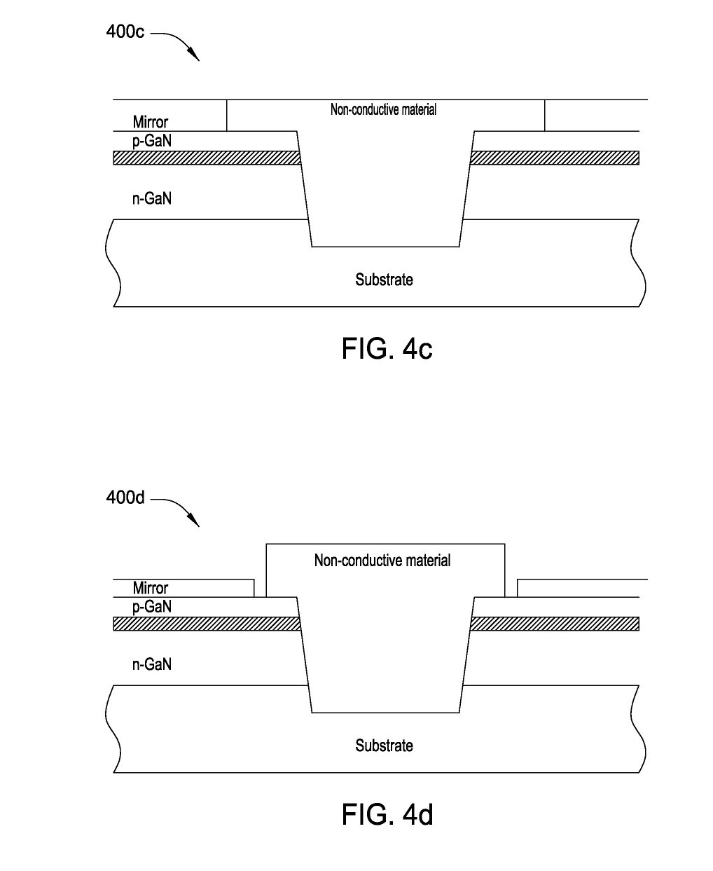

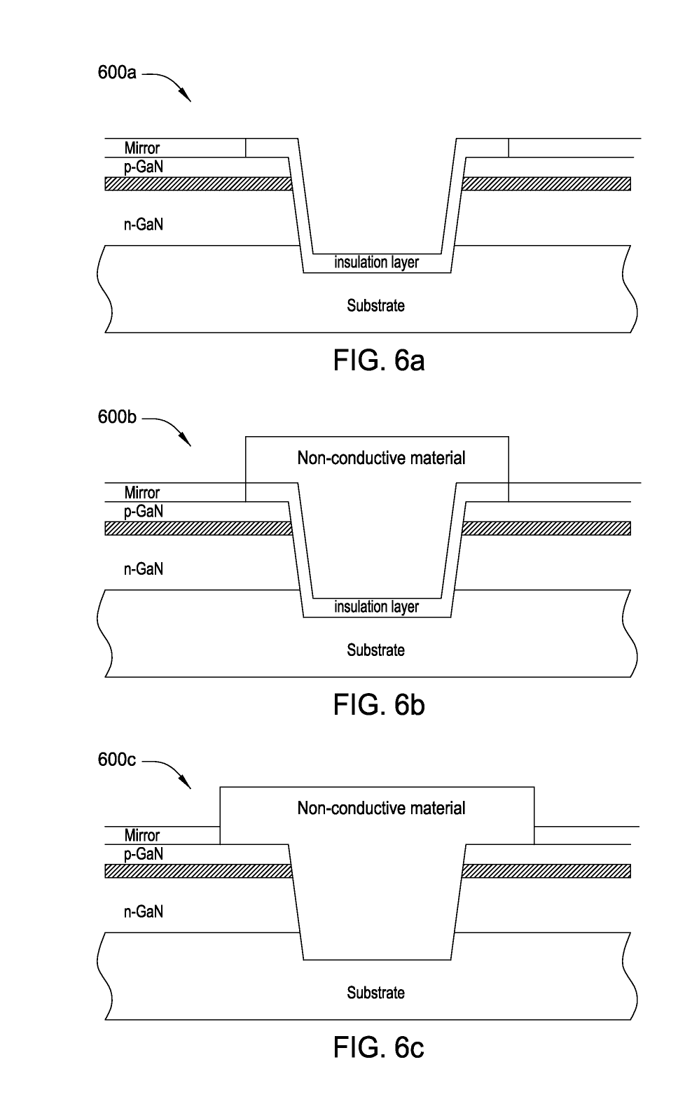

Referring now to FIGS. 3, 4a-d, 5a-c, and 6a-c, a mirror may be formed on top of the p-GaN to act as the reflector for photons. The mirror, by way of example, may be composed of multiple layers, such as Ni/Ag/Ni/Au, Ag/Ni/Au, Ti/Ag/Ni/Au, Ag/Pt or Ag/Pd or Ag/Cr, using an alloy containing Ag, Au, Cr, Pt, Pd, or Al. Optionally, the mirror may be formed after an insulation layer is formed, as shown in FIGS. 6a-b, in an effort to protect the junction areas. In such cases, the mirror may be formed after portions of the insulation layer have been removed from unwanted areas. FIGS. 3, 4a-d, and 6a-c show a variety of different ways to form the mirror on the epitaxial wafer assembly.

One or more electrically insulative layers, which may also be thermally conductive layers, (hereinafter referred to as the “insulation layer”), may be formed on top of the junction to protect the junction, after which portions of the insulation layer may be removed from unwanted areas. For some embodiments, as shown in FIGS. 6a-b, the mirror and the insulation layer may be defined by (i) depositing the insulation layer; (ii) forming a masking layer; (iii) using a wet or dry etch to remove a portion of the insulation layer that is on top of the p-GaN layer; (iv) depositing the mirror; and (v) then lifting off the masking layer so as to leave the mirror on top of the exposed p-GaN.

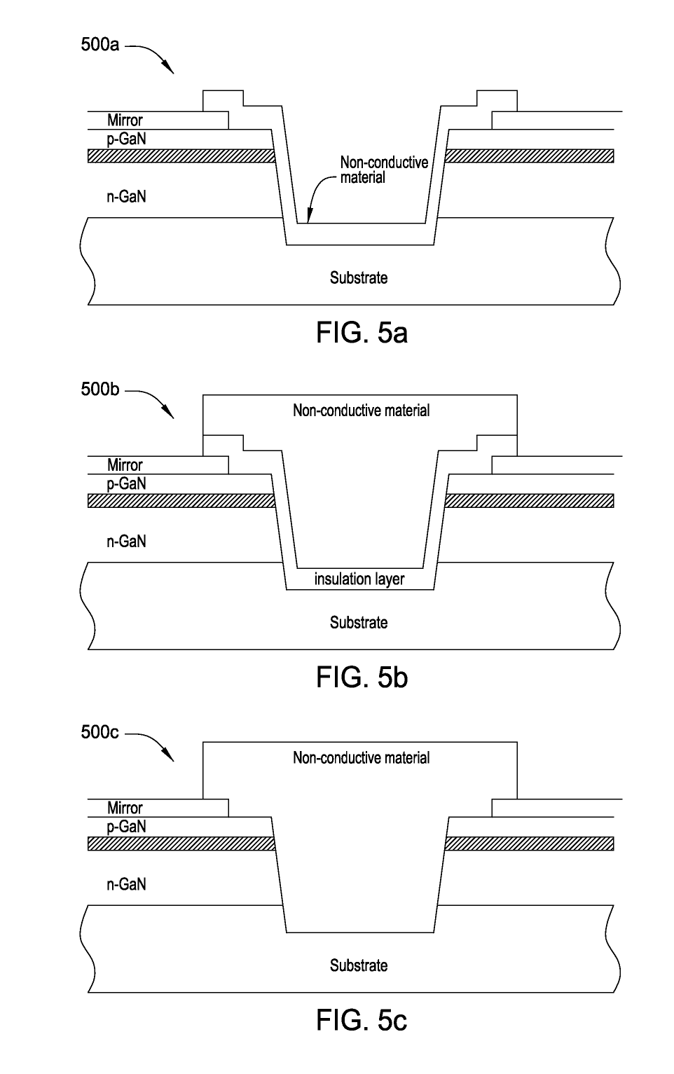

One or more electrically non-conductive layers, which may also be thermally conductive layers, (hereinafter referred to as the “non-conductive material”) may be used to fill the street, the area between the defined devices, and cover at least a portion of the lateral surfaces of the epitaxial structure. The lateral surfaces may be defined as the side surfaces (e.g., non-horizontal surfaces) of the various layers of the epitaxial structure along the trench. The filling of the streets with the non-conductive material may advantageously reduce, absorb, or perhaps stop the interaction of a potentially destructive force (e.g., ultraviolet (UV) light absorption or a laser induced shock wave) that might otherwise damage electrical devices during the separation of the epitaxial wafer assembly. By way of example, the non-conductive material that is used to fill the streets may be an organic material, such as an epoxy, a polymer, a polyimide, thermoplastic, and sol-gel. A photo sensitive organic material, such as SU-8, NR-7, or AZ5214E may also be employed so that one does not have to define the material using a mask. The non-conductive material may also comprise inorganic materials such as SiO2, ZnO, Ta2O5, TiO2, HfO, or MgO. The non-conductive material that fills in the street will also cover the p-GaN as a layer that will further protect the active area, if the insulation layer does not remain over the active area (see FIGS. 5a-c). The non-conductive material may be either above or co-planar with the mirror, which may be multiple layers.

For some embodiments, the insulation layer may be used alone or in conjunction with the non-conductive material. Alternatively, the non-conductive material may be used by itself as seen in FIG. 5c where the insulation layer is not present. Referring to FIG. 5a, moreover, the non-conductive material may not completely fill in the trench for some embodiments. In such cases, the p-GaN may or may not be covered, but at least the MQW layer should be covered by either the non-conductive material or the insulation layer in embodiments where either is employed.

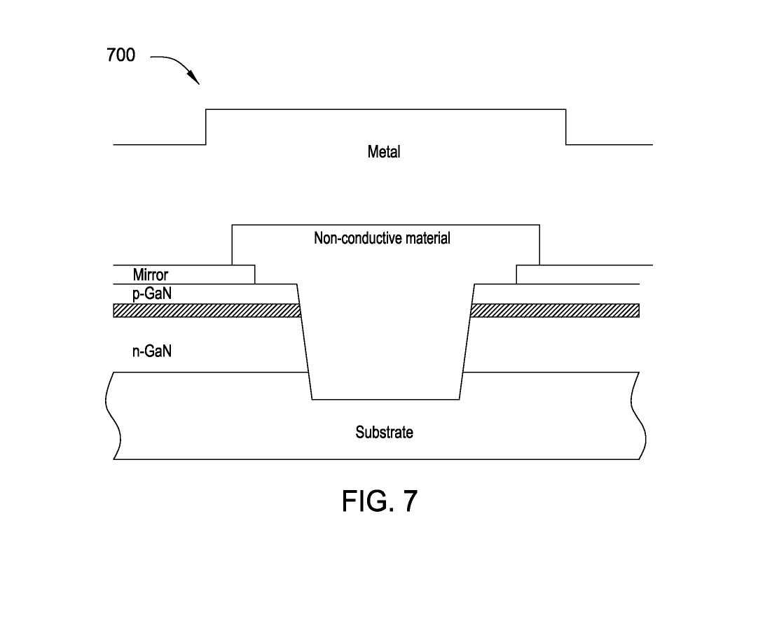

A deposition of one or more metal layers may be made on top of the mirror and the non-conductive material in an effort to create one thick metal plate, for instance, as seen as “metal” in FIG. 7. The metal layer may be single or multi-layered. In cases where the metal layer is a multi-layered structure, a plurality of metal layers with different composition (e.g., Cu, Ni, Ag, Au, Co, Cu—Co, Cu—Mo, Ni/Cu, Ni/Cu—Mo, and their alloys) may be formed, where these layers may be formed using different techniques. The thickness of each metal layer may be about 10˜400 μm.

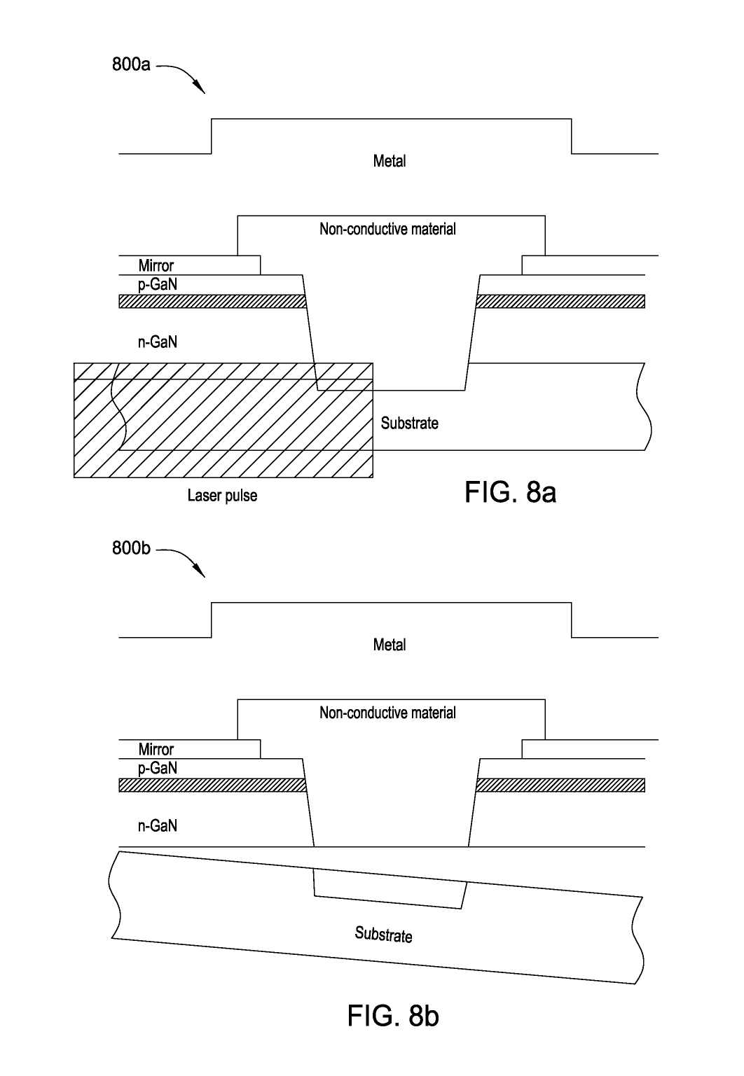

Using various techniques, preferably by a laser operation, the electrical devices fabricated on the epitaxial wafer assembly may be separated from the substrate, as shown in FIGS. 8a-b. This separation may be accomplished by various processes, such as pulse laser irradiation, selected photo enhancement chemical etching of the interfacial layer between the substrate and the GaN, wet etching of the substrate, or lapping/polishing with chemical mechanical polishing.

For some embodiments, the electrical devices fabricated on the epitaxial wafer assembly may be separated from the substrate, as shown in FIG. 8a, using a pulse laser irradiation operation. Such devices may be fabricated in an effort to prevent damage (e.g., cracking) to GaN devices during the separation. Pulse laser irradiation may be used to decompose the interfacial layer of GaN on the substrate and/or remove the electrical devices from the substrate, although the electrical devices may still be held in place where the epitaxial wafer assembly has not been completely removed from the substrate.

The separation of the GaN using pulse laser irradiation may result in its decomposition into Ga and N2, where the ablation of GaN only takes a few nanoseconds in an effort to avoid an explosion with N2 plasma. The light absorption and shock wave generated by the pulse laser irradiation from two laser beams may overlap the street region. As seen in FIG. 8a, the shaded region, which is meant to represent a laser pulse, may partially overlap the substrate such that the laser operation extends all the way into the street.

For some embodiments, the non-conductive material may advantageously reduce, absorb, or stop an interaction of a force (e.g., UV light absorption or a laser induced shock wave) that would otherwise potentially damage adjacent electrical devices during the separation of the devices from the substrate as described herein in relation to FIG. 8a. Upon removal of the substrate in some instances, a portion of the non-conductive material may overlap the newly exposed surface of the n-GaN, although this overlap is not typically desired. For some embodiments, however, additional non-conductive material may be added to cover at least a portion of the newly exposed n-GaN surface.

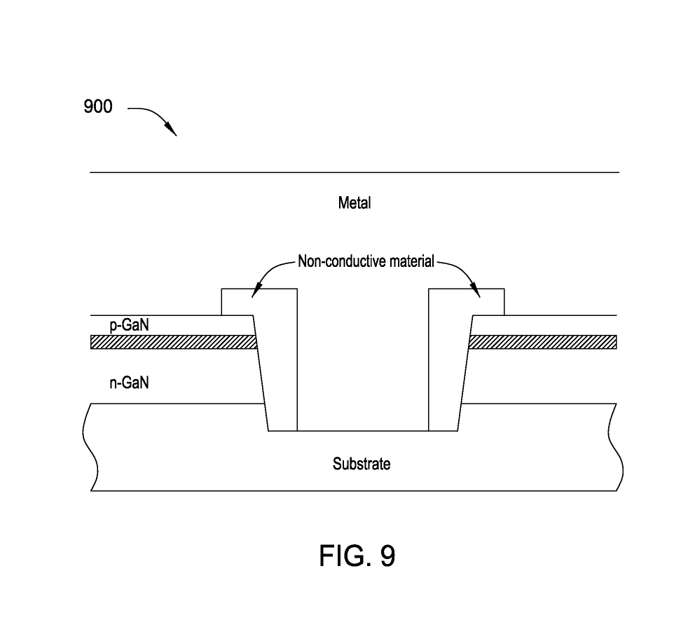

The non-conductive material, which in some embodiments may simply make contact with the substrate rather than penetrate the substrate as shown in FIG. 9, may be chosen as photo-sensitive or non-photo-sensitive material (e.g., polymer, polyimide, SU-8, NR-7, AZ5214E, thermoplastic, ZnO, Ta2O5, TiO2, HfO, or MgO).

After separating the substrate from the epitaxial wafer assembly, the wafer may be diced (i.e., dicing into individual semiconductor dies) using any combination of various suitable techniques. Semiconductor dicing techniques are known to those skilled in the art and will not be described herein.

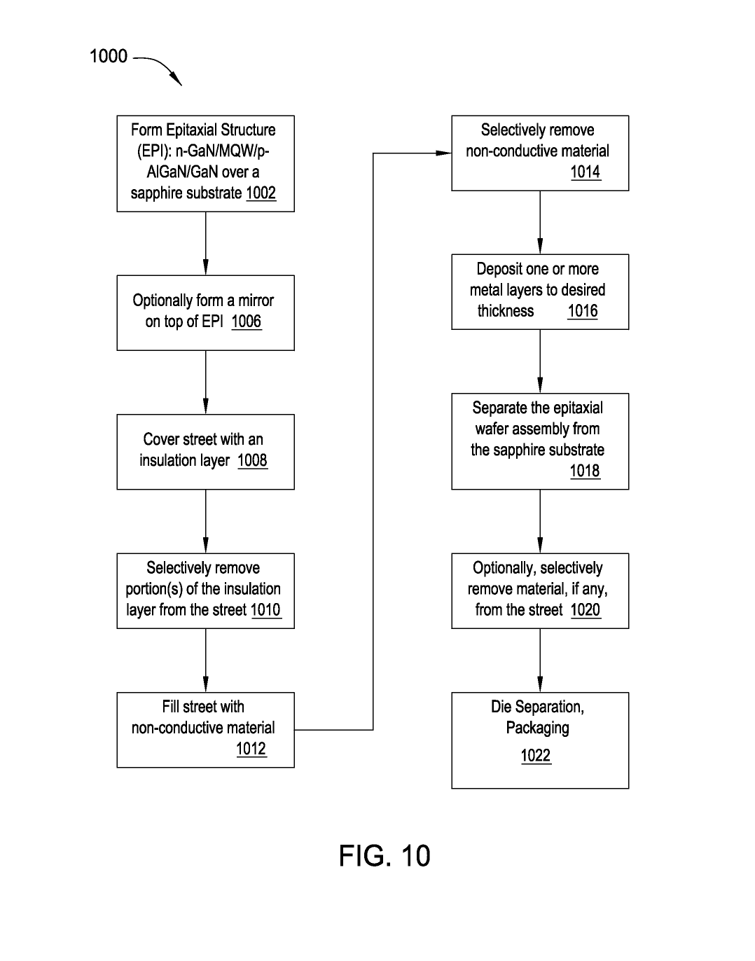

FIG. 10 depicts a process 1000 that is an exemplary implementation for fabricating a VLED. Note that the process 1000 is only an example of one implementation of such a process, that the steps seen in process 1000 may be re-arranged, and that some of the steps may be optional. Process 1000 includes a step 1002 of providing a sapphire substrate and forming an epitaxial structure over the sapphire substrate, where the epitaxial structure may comprise n-GaN/MQW/p-AlGaN/GaN. Optionally, at step 1006, a mirror may be formed on top of the p-GaN. At step 1008, at least portions of the streets may be covered with an insulation layer. As a further option, steps 1006 and 1008 may be reversed. At step 1010, portions of the insulation layer from a street may be selectively removed, and the street may be filled with a non-conductive material in step 1012. The non-conductive material may be selectively removed in step 1014, followed in step 1016 by the growing of one or more metal layers to a desired thickness. In step 1018, the epitaxial structure may be separated from the sapphire substrate. As a further option, in step 1020, material may be selectively removed from the street, and a dicing operation may take place in step 1022. The dicing operation may use any suitable technique. After each die has been separated, packaging and assembly of each die may be performed.

Embodiments disclosed herein may also be applied to the fabrication of GaN-based electronic devices such as power devices, laser diodes, and vertical cavity surface emitting laser device due to its high heat dissipation rate of its metal substrate. Relative to LEDs, the above teaching can improve yield, brightness, and thermal conductivity.

While the foregoing is directed to embodiments of the present invention, other and further embodiments of the invention may be devised without departing from the basic scope thereof, and the scope thereof is determined by the claims that follow.

What is claimed is:

1. A semiconductor die comprising:
a metal substrate;
an epitaxial structure disposed above the metal substrate, comprising:
a p-doped layer coupled to the metal substrate; and
an n-doped layer disposed above the p-doped layer;
an electrically non-conductive material substantially covering lateral surfaces of the epitaxial structure; and
an insulative layer disposed between the lateral surfaces of the epitaxial structure and the electrically non-conductive material.

2. The die of claim 1, wherein the non-conductive material is an organic material comprising at least one of epoxy, a polymer, a polyimide, thermoplastic, or sol-gel.

3. The die of claim 1, wherein the non-conductive material is a photosensitive organic material comprising at least one of SU-8, NR-7, or AZ5214E.

4. The die of claim 1, wherein the non-conductive material is an inorganic material comprising at least one of SiO2, ZnO, Ta2O5, TiO2, HfO, or MgO.

5. The die of claim 1, wherein the non-conductive material does not cover an upper surface of the n-doped layer.

6. The die of claim 1, wherein the non-conductive material covers at least a portion of an upper surface of the n-doped layer.

7. The die of claim 1, wherein the non-conductive material is disposed on a portion of the metal substrate.

8. The die of claim 1, wherein the metal substrate comprises at least one of Cu, Ni, Au, Ag, Co, or alloys thereof.

9. The die of claim 1, wherein the metal substrate comprises a single layer or multiple layers.

10. The die of claim 1, wherein the p-doped layer or the n-doped layer comprises at least one of GaN, AlGaN, InGaN, or AlInGaN.

11. The die of claim 1, further comprising a multiple quantum well (MQW) layer disposed between the p-doped layer and the n-doped layer.

12. The die of claim 1, further comprising a reflective layer disposed between the metal substrate and the p-doped layer.

13. The die of claim 12, wherein the non-conductive material substantially covers lateral surfaces of the reflective layer.

14. The die of claim 12, wherein the reflective layer comprises at least one of Ag, Au, Cr, Pt, Pd, Al, Ni/Ag/Ni/Au, Ag/Ni/Au, Ti/Ag/Ni/Au, Ag/Pt, Ag/Pd, Ag/Cr, or alloys thereof.

15. The die of claim 1, wherein the die is a vertical light-emitting diode (VLED) die, a power device die, a laser diode die, or a vertical cavity surface emitting device die.

16. A vertical light-emitting diode (VLED) die comprising:
a metal substrate;
an epitaxial structure disposed above the metal substrate, comprising:
a p-GaN layer coupled to the metal substrate;
a multiple well quantum (MQW) layer for emitting light coupled to the p-doped layer; and
an n-GaN layer coupled to the MQW layer;
an electrically non-conductive material surrounding the epitaxial structure except for an upper surface of the n-GaN layer and a portion of the p-GaN layer coupled to the metal substrate; and
an insulative layer disposed between the epitaxial structure and the electrically non-conductive material.

17. A semiconductor die comprising:
a metal substrate;
a p-doped layer coupled to the metal substrate;
a multiple quantum well (MQW) layer disposed above the p-doped layer;
an n-doped layer disposed above the MQW layer;
an electrically non-conductive material substantially covering at least lateral surfaces of the MQW layer; and
an insulative layer disposed between the MQW layer and the electrically non-conductive material.
